(19) United States
(12) Patent Application Publication
(10) Pub. No.: US 2009/0175035 A1
(43) Pub. Date: Jul. 9, 2009

(54) LIGHT SOURCE MODULE AND METHOD FOR MANUFACTURING SAME

(75) Inventor: WEN-JANG JIANG, Chu-Nan (TW)

Correspondence Address: PCE INDUSTRY, INC.;ATT. Steven Reiss, 458 E. LAMBERT ROAD, FULLERTON, CA, 92835, US

(73) Assignee: FOXSEMICON INTEGRATED TECHNOLOGY, INC., Chu-Nan (TW)

(21) Appl. No.: 12/330,558

(22) Filed: Dec. 9, 2008

(30) Foreign Application Priority Data
Jan. 3, 2008 (CN) 200810300012.0

(51) Int. Cl. F21V 33/00; H01L 21/50

(52) U.S. Cl. 362/234; 438/28; 257/E33.056

(57) ABSTRACT

An exemplary embodiment of a light source module includes a lighting module and a thermoelectric cooler. The lighting module includes a first heat-conducting dielectric plate and a plurality of LED chips arranged on the first heat-conducting dielectric plate. The thermoelectric cooler is formed on an opposite side of the first heat-conducting dielectric plate to the LED chips. The thermoelectric cooler includes a second heat-conducting dielectric plate opposite to the first heat-conducting dielectric plate, and a plurality of thermoelectric elements located between the first heat-conducting dielectric plate and the second heat-conducting dielectric plate. The thermoelectric elements are connected with each other.

### CROSS-REFERENCE TO RELATED APPLICATIONS

This application is related to the following commonly-assigned copending application Ser. No. 12/206,171, entitled “ILLUMINATION DEVICE”. Disclosure of the above-identified application is incorporated herein by reference.

### BACKGROUND

1. Technical Field

The present invention relates to light source modules, particularly, to a light source module with a high heat-dissipation efficiency and method for manufacturing same.

2. Description of Related Art

A light emitting diode (LED) is one type of semiconductor light source, and the electrical and optical characteristics and life span thereof are greatly temperature-dependent. Generally, a high working temperature will cause a deterioration of an internal quantum efficiency of the LED and shorten the life span thereof. Furthermore, a resistance of a semiconductor has a negative temperature coefficient and tends to be reduced with an increase in the working temperature. Such a reduced resistance will correspondingly result in a larger current at a given voltage and the generation of excessive heat. If the excessive heat cannot be effectively dissipated, a phenomenon of heat accumulation will be difficult to avoid, and, accordingly, the deterioration of the LED may accelerate.

Referring to FIG. 10, a typical light source module 100 includes a printed circuit board 101, a plurality of LEDs 102 and a heat-dissipating member 103. The printed circuit board 101 defines two opposite surfaces (not labeled). The heat-dissipating member 103 and the LEDs 102 are respectively mounted on the two opposite surfaces of the printed circuit board 101. The heat-dissipating member 103 is thermally connected with the printed circuit board 101, with thermal grease or paste interposed therebetween to promote heat conduction. Such heat-dissipating member 103 is configured (i.e., structured and arranged) for facilitating the dissipation of heat from the light source module 100. The LEDs 102 are electrically connected with the printed circuit board 101.

However, the LEDs 102 are spaced from the heat-dissipating member 103 via the printed circuit board 101, which has a relatively low thermal conductivity (i.e., acts more like a thermal insulator). Due to such presence of the printed circuit board 101, heat generated from the LEDs 102 during operation would not be immediately transmitted to the heat-dissipating member 103, thus not permitting effective heat dissipation. As such, the above-described phenomenon of heat accumulation will likely appear, and the deterioration of the light source module 100 would be accelerated.

Therefore, what is needed is to provide a light source module with high heat-dissipation efficiency and method for manufacturing same.

### BRIEF DESCRIPTION OF THE DRAWINGS

Many aspects of the present light source module can be better understood with reference to the following drawings. The components in the drawings are not necessarily drawn to scale, the emphasis instead being placed upon clearly illustrating the principles of the present light source module. Moreover, in the drawings, like reference numerals designate corresponding parts throughout the several views.

FIG. 1 is a schematic, cross-sectional view of a light source module, in accordance with a first embodiment.

FIG. 2 is a schematic, cross-sectional view of the light source module with a light emitting diode having flip-chip chips.

FIG. 3 is a schematic, state view of a circuit layer and a number of LED chips are formed on a first surface of the first heat-conducting dielectric plate.

FIG. 4 is a schematic, state view of a protective layer is formed on the first surface of the first heat-conducting dielectric plate of FIG. 3.

FIG. 5 is a schematic, state view of a number of the thermoelectric cooling units are mounted on a second surface of the first heat-conducting dielectric plate of FIG. 4.

FIG. 6 is a schematic, state view of the protective layer is removed from the first surface of the first heat-conducting dielectric plate of FIG. 5.

FIG. 7 is a schematic, state view of each of the LED chips is packaged by a package of FIG. 6.

FIG. 8 is a schematic, state view of a circuit layer is formed on a first surface of the first heat-conducting dielectric plate, and a number of LED chips are flip-chip bonded on the first surface of the first heat-conducting dielectric plate.

FIG. 9 is a schematic, state view of a protective layer is formed on the first surface of the first heat-conducting dielectric plate of FIG. 8.

FIG. 10 is a schematic, side view of a typical light source module.

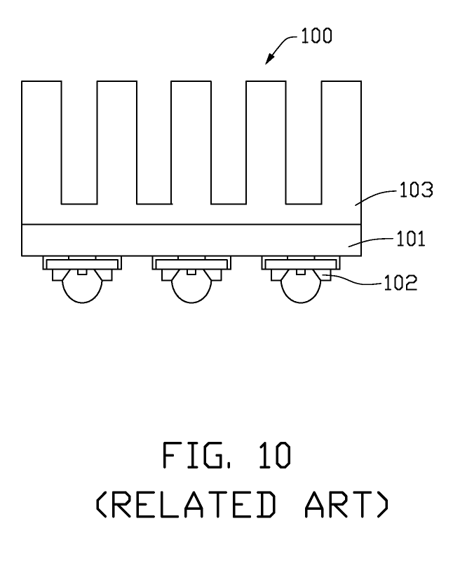

The exemplifications set out herein illustrate at least one exemplary embodiment, in one form, and such exemplifications are not to be construed as limiting the scope of the present light source module in any manner.

### DETAILED DESCRIPTION

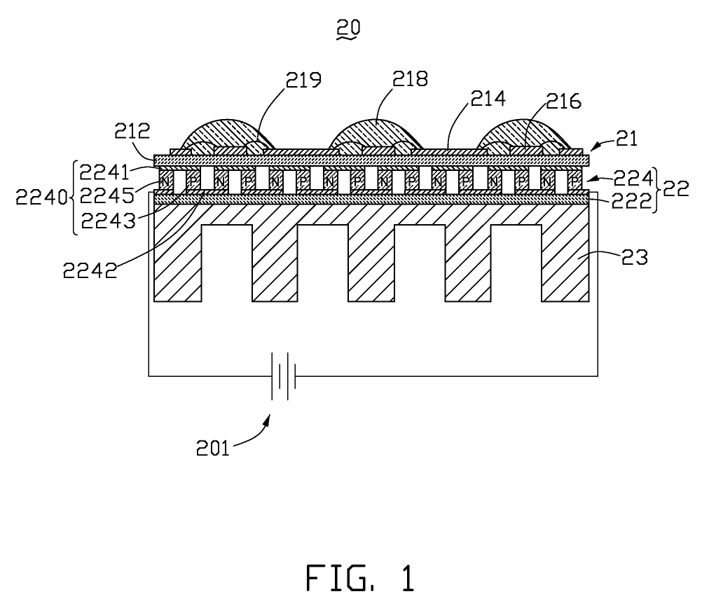

Referring to FIG. 1, a light source module 20, in accordance with an exemplary embodiment, is provided. The light source module 20 includes a lighting module 21 and a thermoelectric cooler (hereinafter, TEC) 22.

The lighting module 21 includes a first heat-conducting dielectric plate 212, a circuit layer 214 formed on the first heat-conducting dielectric plate 212, a plurality of LED chips 216 arranged on the first heat-conducting dielectric plate 212, and a plurality of encapsulations 218 respectively covers the LED chips 216. In the exemplary embodiment, the LED chips 216 are formed on a mounting surface (not labeled) of the first heat-conducting dielectric plate 212 by an epitaxial growth method, and the LED chips 216 are electrically connected to the circuit layer 214 by metal wires 219.

The first heat-conducting dielectric plate 212 may be a sapphire substrate with electrical insulating character and excellent thermal conductive performance. It can be understood that, the first heat-conducting dielectric plate 212 may also be a silicon carbide substrate, or other III-V compound, II-VI compound semiconductor substrate.

The thermoelectric cooler 22 includes a second heat-conducting dielectric plate 222 and a thermoelectric cooling element group 224. The second heat-conducting dielectric plate 222 is disposed on one side of the LED chips 216 opposite to the first heat-conducting dielectric plate 212. The thermoelectric cooling element group 224 is sandwiched between the first heat-conducting dielectric plate 212 and the second heat-conducting dielectric plate 222, and thermally connected to the first heat-conducting dielectric plate 212 and the second heat-conducting dielectric plate 222.

The second heat-conducting dielectric plate 222 may also be a sapphire substrate or a silicon carbide substrate with electrical insulating character and excellent thermal conductive performance. The light source module 20 further includes a number of heat-dissipating fins 23 located on the second heat-conducting dielectric plate 222. The heat-dissipating fins 23 extend in a direction away from the first heat-conducting dielectric plate 212 for facilitating the dissipation of heat from the light source module 20.

The thermoelectric cooling element group 224 includes a plurality of thermoelectric elements 2240 and a plurality of electric slices 2242. The thermoelectric elements 2240 are evenly distributed between the first heat-conducting dielectric plate 212 and the second heat-conducting dielectric plate 222 in an array. All of the thermoelectric elements 2240 are electrically connected in series, and electrically connected to a direct current electrical source 201. That is, each two adjacent thermoelectric elements 2240 are electrically connected with each other. In other embodiments, some thermoelectric elements 2240 may be connected in series, and the remaining thermoelectric elements 2240 may be connected in parallel. Each of the thermoelectric elements 2240 includes a conductive substrate 2241, a P-type semiconductor 2243, and an N-type semiconductor 2245. The P-type and N-type semiconductors 2243, 2245 are both located at one side of the conductive substrate 2241 and electrically connected to the conductive substrate 2241. The conductive substrate 2241 is mounted to the first heat-conducting dielectric plate 212 facing towards the second heat-conducting dielectric plate 222. The P-type and N-type semiconductors 2243, 2245 are parallel to each other and located on the conductive substrate 2241 facing away the first heat-conducting dielectric plate 212. The electric slice 2242 is mounted to the second heat-conducting dielectric plate 222 facing towards the first heat-conducting dielectric plate 212, and electrically connected with a P-type semiconductor 2243 of one thermoelectric element 2240 and an N-type semiconductor 2245 of the adjacent thermoelectric element 2240.

Each of the P-type semiconductors 2243 and the N-type semiconductors 2245 is a solid state block made of a compound semiconductor selected from the group consisting of Bi—Te based semiconductors, Sb—Te based semiconductors, Bi—Se based semiconductors, Pb—Te based semiconductors, Ag—Sb—Te based semiconductors, Si—Ge based semiconductors, Fe—Si based semiconductors, Mn—Si based semiconductors and Cr—Si based semiconductors. In the present embodiment, each of the P-type semiconductors 2243 and the N-type semiconductors 2245 is a Bi2Te3 based semiconductor.

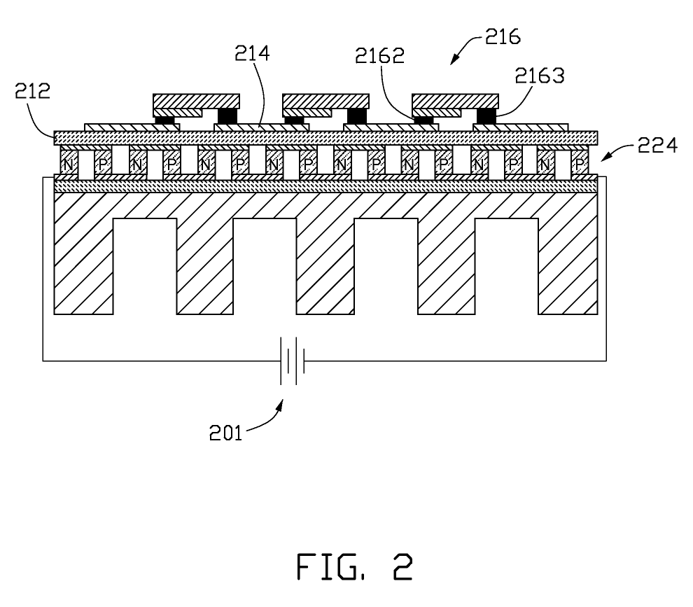

Referring to FIG. 2, the LED chips 216 are flip-chip bonded on the first heat-conducting dielectric plate 212 facing away from the second heat-conducting dielectric plate 222. That is, each LED chip 216 is equipped with a first electrical contact 2162 and a second electrical contact 2163 paired with the first electrical contact 2162. The LED chips 216 are electrically connected with the circuit layer 214 via the respective paired first and second electrical contacts 2162, 2163. The paired first and second electrical contact 2162, 2163 are soldered with the circuit layer 214.

The thermoelectric elements 2240 may generate Peltier Effect therein, when the direct current electrical source 201 supplies power to the thermoelectric elements 2240. Heat generated from the LED chips 216 can be effectively transferred from the end of the thermoelectric cooling element group 224 close to the first heat-conducting dielectric plate 212 to the other end of that close to the second heat-conducting dielectric plate 222 by the P-type and N-type semiconductors 2243, 2245. Because the first heat-conducting dielectric plate 212 has an increase thermal conductive performance, the P-type and N-type semiconductors 2243, 2245 have a higher performance. Thus, the heat generated from the LED chips 216 can be effectively transmitted to the second heat-conducting dielectric plate 222, and then quickly dissipated by the heat-dissipating fins 23.

The operating temperature of the thermoelectric cooler 22 can be controlled by regulating the voltage that the direct current electrical source 201 supplied, so the heat-dissipation efficiency of LED chips 216 can be accurately controlled by the thermoelectric cooler 22, such that the LED chips 216 can work at a constant temperature range, to ensure the LED chips 216 have stable photo-electric characteristics and improve work efficiency of the light source module 20. Because the thermoelectric cooler 22 is directly positioned on an opposite side of the first heat-conducting dielectric plate 212 to the LED chips 216, heat generated from the LED chips 216 in operation can be immediately transmitted to the thermoelectric cooler 22 in a short distance, which could effectively improve the heat-dissipation efficiency of LED chips 216 by the thermoelectric cooler 22. In addition, the heat-dissipating fins 23 dissipates the heat of the second heat-conducting dielectric plate 222 in a timely matter, thereby the light source module 20 is cooled effectively.

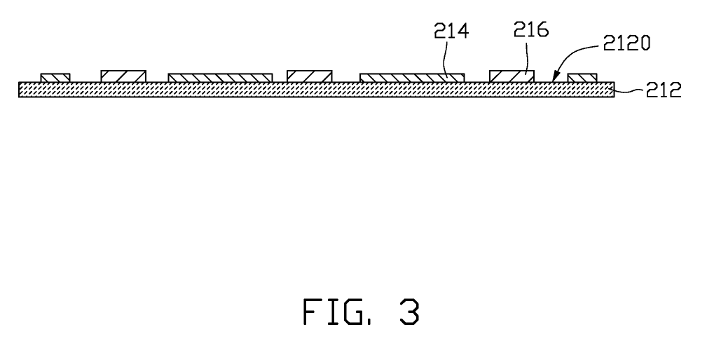

Referring to FIG. 3 to FIG. 8, a method for manufacturing the above-described light source module 20 is recited below, in according to a second embodiment.

In a general first step, referring to FIG. 3, providing a first heat-conducting dielectric plate 212, forming a number of LED chips 216 on a first surface 2120 of the first heat-conducting dielectric plate 212, and forming a circuit layer 214 on the first surface 2120 of the first heat-conducting dielectric plate 212 by vapor deposition method or electroplating process. Usefully, the first heat-conducting dielectric plate 212 is made of sapphire, silicon carbide, III-V group compound based semiconductor, or II-VI group compound based semiconductor. Specifically, the LED chips 216 are formed on the first heat-conducting dielectric plate 212 by an epitaxial growth method.

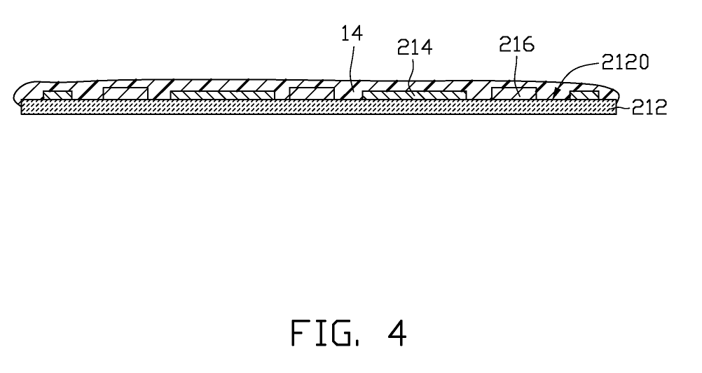

In a general second step, referring to FIG. 4, a protective layer 14 is formed on the first surface 2120 of the first heat-conducting dielectric plate 212 to encapsulate the LED chips 216 and the circuit layer 214. As a result, the LED chips 216 and the circuit layer 214 are isolated from outside (e.g., atmosphere or other pollutant). In the present embodiment, the protective layer 14 is a black wax.

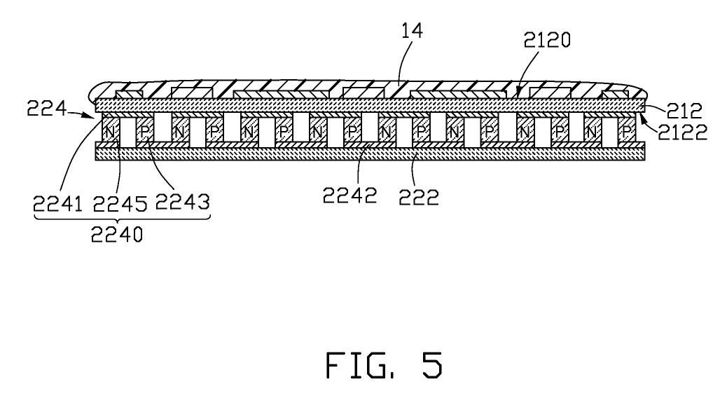

In a general third step, referring to FIG. 5, a number of the thermoelectric cooling units 2240 are mounted on a second surface 2122 of the first heat-conducting dielectric plate 212. In detail, an array of conductive substrates 2241 is respectively formed on the second surface 2122 by vapor deposition method or electroplating process, and a P-type semiconductors 2243 and an N-type semiconductors 2245 are attached to each of the conductive substrate 2241 by use of conductive adhesive applied between the semiconductors 2243, 2245 and the conductive substrate 2241 so as to paste and fix the P-type and N-type semiconductors 2243, 2245 on the conductive substrate 2241, thereby many thermoelectric cooling units 2240 can be formed. The conductive adhesive can be silver colloid. Then, a number of electrically conductive pads 2242 are attached to one side of the thermoelectric cooling units 2240 away from the first heat-conducting dielectric plate 212. The electrically conductive pads 2242 are electrically connecting the P-type semiconductors 2243 to the adjacent N-type semiconductors 2245, thereby the thermoelectric cooling element group 224 can be assembled by connecting the thermoelectric cooling units 2240 in series.

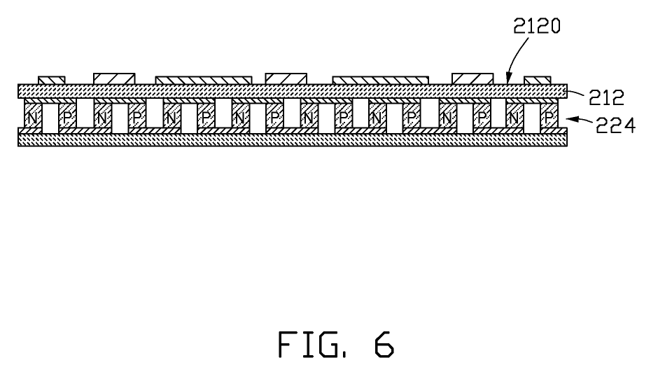

In a general fourth step, referring to FIG. 6, the protective layer 14 is removed from the first surface 2120 of the first heat-conducting dielectric plate 212 using chemical reagent such as isopropanol.

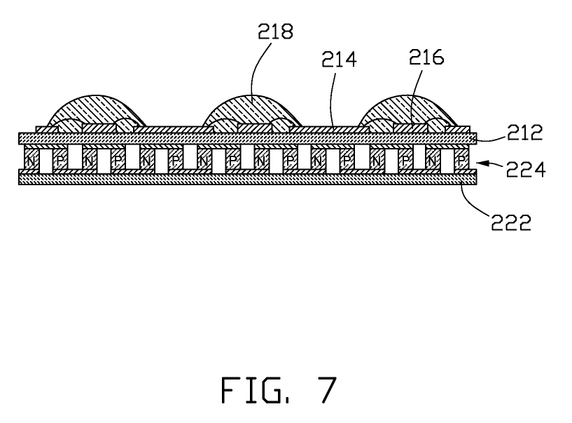

In a general fifth step, referring to FIG. 7, each of the LED chips 216 is packaged by a package 218. The packaging process includes several sub-processes, e.g., wiring-bonding and encapsulating. In the wiring-bonding process, a number of electrical wires are applied to electrically connect the LED chips 216 to the circuit layer 214. In detail, an end of each of the electrical wire is electrically connected with each of LED chips 216, and another end of the electrical wire is electrically connected with the circuit layer 214. After the wiring-bonding process is finished, the packages 218 are applied to the first heat-conducting dielectric plate 212 to respectively encapsulate the LED chips 216 therein.

In a general sixth step, a heat-dissipating fins 23 is thermally coupled to the second heat-conducting dielectric plate 222. Specifically, the heat-dissipating fins 23 is attaching to the second heat-conducting dielectric plate 222 facing away from the first heat-conducting dielectric plate 212 by use of conductive adhesive.

It can be understood that, the “wiring-bonding process” in the fifth step may be accomplished in the first step, and according to actual requirement, the second and fourth steps may be canceled.

In this embodiment, the LED chips 216 and the circuit layer 214 are formed on the first surface 2120 of the first heat-conducting dielectric plate 212 firstly, and then the thermoelectric cooler 22 is formed on the second surface 2122 of the first heat-conducting dielectric plate 212, thereby one heat-conducting dielectric plate is utilized jointly by the LED chips 216, the circuit layer 214 and the thermoelectric cooler 22. As a result, the heat generated by the LED chips 216 can be quickly taken away by the thermoelectric cooler 22.

A method for manufacturing the above-described light source module 20 is recited below, in according to a third embodiment.

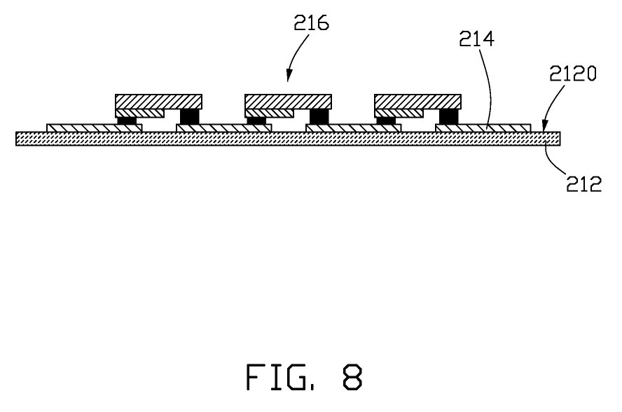

In a general first step, referring to FIG. 8, a first heat-conducting dielectric plate 212 is provided, and a circuit layer 214 is formed on a first surface 2120 of the first heat-conducting dielectric plate 212. The LED chips 216 are flip-chips and are bonded on the first surface 2120 of the first heat-conducting dielectric plate 212, and electrically connected to the circuit layer 214.

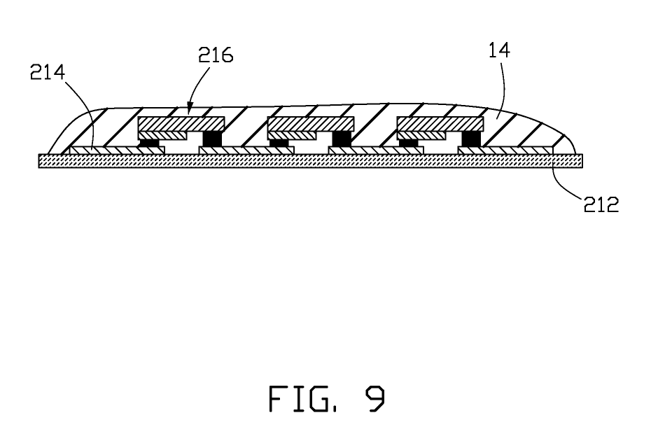

In a general second step, referring to FIG. 9, a protective layer 14 is formed on the first heat-conducting dielectric plate 212 to encapsulate the LED chips 216 and the circuit layer 214. As a result, the LED chips 216 and the circuit layer 214 are isolated from outside (e.g., atmosphere or other pollutant). In the present embodiment, the protective layer 14 is a black wax.

In a general third step, a thermoelectric cooler is formed on a second surface of the first heat-conducting dielectric plate opposite to the first surface of the first heat-conducting dielectric plate, as described in above second embodiment.

In a general fourth step, the protective layer is removed from the first surface of the first heat-conducting dielectric plate, as described in above second embodiment.

In a general fifth step, the heat-dissipating fins is thermally coupled to the thermoelectric cooler facing away from the first heat-conducting dielectric plate.

In this embodiment, the circuit layer 214 is formed on the first surface 2120 of the first heat-conducting dielectric plate 212 and the LED chips 216 are also flip-chip bonded on the first surface 2120 firstly, and then the thermoelectric cooler is formed on an opposite second surface of the first heat-conducting dielectric plate, thereby one heat-conducting dielectric plate is utilized jointly by the LED chips 216, the circuit layer 214 and the thermoelectric cooler. As a result, the heat generated by the LED chips 216 can be quickly taken away by the thermoelectric cooler.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the present invention.

What is claimed is:

1. A light source module comprising:
a lighting module comprising a first heat-conducting dielectric plate and a plurality of LED chips arranged on the first heat-conducting dielectric plate; and
a thermoelectric cooler formed on an opposite side of the first heat-conducting dielectric plate to the LED chips, the thermoelectric cooler comprising a second heat-conducting dielectric plate opposite to the first heat-conducting dielectric plate, and a plurality of thermoelectric elements located between the first heat-conducting dielectric plate and the second heat-conducting dielectric plate, the thermoelectric elements being connected with each other.

2. The light source module of claim 1, wherein the first heat-conducting dielectric plate includes a mounting surface, the LED chips being formed on the mounting surface of the first heat-conducting insulated plate by an epitaxial growth method.

3. The light source module of claim 2, wherein the lighting module includes a circuit layer being formed on and in contact with the mounting surface.

4. The light source module of claim 1, wherein the LED chips are flip-chips and are bonded on the first heat-conducting dielectric plate.

5. The light source module of claim 1, further comprising a plurality of heat-dissipating fins being located on the second heat-conducting dielectric plate and extending in a direction away from the first heat-conducting dielectric plate.

6. The light source module of claim 1, wherein the thermoelectric elements each includes a conductive substrate, a P-type semiconductor, and an N-type semiconductor, the P-type and N-type semiconductors are parallel to each other and electrically connected to the conductive substrate, each two adjacent thermoelectric elements are electrically connected with each other.

7. A method for manufacturing a light source module comprising:
(1) providing a first heat-conducting dielectric plate;
(2) forming a plurality of LED chips on the first surface of the first heat-conducting dielectric plate;
(3) forming a circuit layer on a first surface of the first heat-conducting dielectric plate;
(4) forming a thermoelectric cooler on an opposite second surface of the first heat-conducting dielectric plate, the thermoelectric cooler including a second heat-conducting dielectric plate and a plurality of thermoelectric cooling elements being connected with each other, the second heat-conducting dielectric plate being opposite to the first heat-conducting dielectric plate, the thermoelectric cooling elements being sandwiched between the first heat-conducting dielectric plate and the second heat-conducting dielectric plate, and the thermoelectric cooling elements being thermally connected to the first heat-conducting dielectric plate and the second heat-conducting dielectric plate.

8. The method as claimed in claim 7, wherein the LED chips are formed on the first surface of the first heat-conducting dielectric plate by an epitaxial growth method.

9. The method as claimed in claim 7, wherein the LED chips are flip-chips and are bonded on the first heat-conducting dielectric plate.

10. The method as claimed in claim 7, further comprising forming a protective layer on the first surface of the first heat-conducting dielectric plate to encapsulate the LED chips and the circuit layer, prior to step (4).

11. The method as claimed in claim 7, further comprising attaching a plurality of heat-dissipating fins on the second heat-conducting dielectric plate after the step (4).

12. The method as claimed in claim 7, wherein the step (4) further comprises:
forming an array of the conductive substrates on the second surface of the first heat-conducting dielectric plate;
attaching a P-type semiconductor and an N-type semiconductor to each of the conductive substrates, the P-type semiconductors and the N-type semiconductors electrically connected to the conductive substrate to form the thermoelectric cooling units;
providing the second heat-conducting dielectric plate with a plurality of electrically conductive pads; and
attaching the heat-conducting dielectric plate to the thermoelectric cooling units, the electrically conductive pads electrically connecting the P-type semiconductors to the adjacent N-type semiconductors, thereby the thermoelectric cooling units being connected in series.
